(19) United States
(12) Patent Application Publication
(10) Pub. No.: US 2025/0346988 A1
(43) Pub. Date: Nov. 13, 2025

(54) GYRIFIED METAL-ELASTOMER COMPOSITE AND METHOD FOR MANUFACTURING THE SAME

(71) Applicants: UNIVERSITY -INDUSTRY COOPERATION GROUP OF KYUNG HEE UNIVERSITY, Yongin-si (KR); GACHON UNIVERSITY OF INDUSTRY-ACADEMIC COOPERATION FOUNDATION, Seongnam-si (KR); KOREA UNIVERSITY OF TECHNOLOGY AND EDUCATION INDUSTRY-UNIVERSITY COOPERATION FOUNDATION, Cheonan-si (KR)

(72) Inventors: Jin Young OH, Anyang-si (KR); Rae II LEE, Seoul (KR); Soosnag CHAE, Sejong-si (KR)

(73) Assignees: UNIVERSITY -INDUSTRY COOPERATION GROUP OF KYUNG HEE UNIVERSITY, Yongin-si (KR); GACHON UNIVERSITY OF INDUSTRY-ACADEMIC COOPERATION FOUNDATION, Seongnam-si (KR); KOREA UNIVERSITY OF TECHNOLOGY AND EDUCATION INDUSTRY-UNIVERSITY COOPERATION FOUNDATION, Cheonan-si (KR)

(21) Appl. No.: 19/198,351

(22) Filed: May 5, 2025

(30) Foreign Application Priority Data
May 8, 2024 (KR) 10-2024-0060375

(51) Int. Cl. C23C 14/20; C08G 77/12; C08G 77/20; C23C 14/24

(52) U.S. Cl. CPC C23C 14/20; C08G 77/12; C08G 77/20; C23C 14/24

(57) ABSTRACT

According to one embodiment, the present invention relates to a gyrified metal-elastomer composite and a method for manufacturing the same. In this embodiment of the invention, a gyrified metal-elastomer composite with nanoscale phases can be dynamically controlled and manufactured. The gyrified metal-elastomer composite simultaneously retains the electrical conductivity of the metal and the stretchability of the elastomer, making it suitable for use in stretchable electronic devices.

### CROSS-REFERENCE TO RELATED APPLICATION

This application claims priority from and the benefit of Korean Patent Application No. 10-2024-0060375 filed on May 8, 2024, in the Korean Intellectual Property Office, the disclosure of which is incorporated herein by reference.

### BACKGROUND OF THE DISCLOSURE

### Field of the Disclosure

Example embodiments relate to a gyrified metal-elastomer composite and a method for manufacturing the same. More specifically, the present invention relates to a gyrified metal-elastomer composite that spontaneously forms gyrifications without degrading the inherent properties of the metal and elastomer, and a method for manufacturing the same.

### Description of the Related Art

Nanophase mixtures serve as components of functional composites because they have the potential to maximize synergy by leveraging the advantages of each constituent. However, attempts to combine materials with insufficient interaction between components often lead to thermodynamically driven phase separation, which hinders the blending of chemical and physical properties in nanophase composites. This issue is particularly pronounced in composites of metals and elastomers aimed at creating stretchable conductive membranes. As such, developing membranes capable of combining conductivity akin to metals, elasticity like rubber, mechanical durability, and physicochemical resilience has been a long-standing research challenge.

Although simple physical mixing of metallic nanoparticles (or nanowires) and elastomer precursors or in-situ reduction of metal nanostructures within elastomers has been demonstrated, achieving conductive metal-elastomer nanophase composites remains a difficult task. To date, studied metal-elastomer composites have suffered from issues such as low electrical conductivity or diminished mechanical stretchability and elasticity.

As an alternative, the present invention provides a metal-elastomer nanophase composite, which can be particularly beneficial for bioelectronic applications where long-term stable operation within the human body is required. In this field, customized metal-elastomer nanophases must excel in electrical performance, mechanical durability, and environmental resilience. Each of these characteristics originates from the respective metal and elastomer components. Nanoscale mixing not only creates a large interface that enhances adhesion between metals and polymers but also offers softened metallic nanoparticles and nanostructures due to high surface excess elasticity.

The method of depositing noble metals onto elastomeric templates has been previously employed for stretchable conductors. A well-known approach involves thermally depositing gold (Au) onto styrene-ethylene-butylene-styrene (SEBS) thermoplastic elastomer templates. During deposition, Au nanoparticles interpenetrate the SEBS elastomer, forming a biphasic metal-elastomer layer, which enables the creation of stretchable metal conductors. However, planar Au layers are prone to cracking under micro- or nanoscale deformation, thereby limiting their mechanical applicability. Furthermore, thermoplastic elastomers are vulnerable to heat and organic solvents, restricting their use in environmentally challenging conditions.

Even when nanoblending immiscible materials is thermodynamically unfavorable, kinetics can provide a means to overcome the limitations imposed by the physical and chemical properties of materials. The present invention employs a kinetically controlled method to form energetically unfavorable but well-mixed metal-elastomer nanophases.

### SUMMARY

According to one embodiment, the objective is to provide a metal-elastomer composite that retains the elasticity of the elastomer and the electrical conductivity of the metal.

According to one embodiment, the objective is to provide a metal-elastomer composite that includes a single layer in which the metal and elastomer are nanoblended and chemically bonded.

According to one embodiment, the objective is to provide a stretchable material that maintains electrical conductivity even under applied areal strain, exhibits durability in harsh environments, and demonstrates excellent resilience by controlling the dynamics between the metal and elastomer.

A method for manufacturing a gyrified metal-elastomer composite according to one embodiment may include: mixing a prepolymer and a crosslinker to form an elastomer; depositing a metal onto the elastomer to form a metal-elastomer composite with the metal embedded in the elastomer; and self-forming gyrifications on the metal-elastomer composite.

In one embodiment, the step of forming the metal-elastomer composite may include: integrating the metal with the elastomer at the molecular level; and facilitating the growth of the metal in the z-axis direction within the elastomer matrix.

In one embodiment, in the step of facilitating the growth of the metal in the z-axis direction within the elastomer matrix, the metal may grow in the form of nano-needles while being deposited.

In one embodiment, when the prepolymer and the crosslinker are mixed at a weight ratio of 5:1 to 10:1, the deposited metal may have a thickness of 7.5 nm to 12.5 nm.

In one embodiment, when the prepolymer and the crosslinker are mixed at a weight ratio of 3.5:1 to 5:1, the deposited metal may have a thickness of 12.5 nm to 37.5 nm.

In one embodiment, when the prepolymer and the crosslinker are mixed at a weight ratio of 3:1 to 4:1, the deposited metal may have a thickness of 37.5 nm to 87.5 nm.

In one embodiment, when the prepolymer and the crosslinker are mixed at a weight ratio of 3:1 to 3.5:1, the deposited metal may have a thickness of 87.5 nm to 125 nm.

In one embodiment, when the prepolymer and the crosslinker are mixed at a weight ratio of 2.5:1 to 3.5:1, the deposited metal may have a thickness of 125 nm to 250 nm.

In one embodiment, in the step of self-forming gyrifications on the metal-elastomer composite, the metal-elastomer composite may undergo gyrification.

In one embodiment, the step of self-forming gyrifications on the metal-elastomer composite may be performed for 0.5 hours to 36 hours.

In one embodiment, the gyrifications of the gyrified metal-elastomer composite may have a gyrified structure.

In one embodiment, the gyrified metal-elastomer composite may be characterized by the elastomer and the metal being chemically bonded at the nanoscale.

In one embodiment, the thickness of the metal in the gyrified metal-elastomer composite may range from 10 nm to 10,000 nm.

In one embodiment, the electrical conductivity of the gyrified metal-elastomer composite may range from 1.0×10² S/cm to 1.0×10⁶ S/cm under an areal strain of 100% to 156%.

In one embodiment, the gyrified metal-elastomer composite may exhibit an electrical conductivity of 1.0×10² S/cm to 1.0×10⁶ S/cm in a solution with a pH ranging from 2 to 13.

According to an embodiment of the present invention, a novel method for mixing metal and elastomer at the nanoscale can be provided to address the mixing challenges caused by the thermodynamic immiscibility of metal and elastomer.

Additionally, according to another embodiment of the present invention, a high-performance stretchable electronic device can be developed by forming a composite that simultaneously possesses the electrical conductivity of metal and the stretchability of elastomer, which are essential for stretchable devices.

### BRIEF DESCRIPTION OF THE FIGURES

Embodiments will be described in more detail with regard to the figures, wherein like reference numerals refer to like parts throughout the various figures unless otherwise specified, and wherein:

FIGS. 1A to 1I are schematic diagrams illustrating spontaneously formed metal-elastomer nanophase composites and nanoscale three-dimensional (3D) structures.

FIGS. 2A to 2C are schematic diagrams and graphs related to the growth of Au-PDMS nanophase composites controlled by chemical kinetics.

FIGS. 3A to 3D present the analysis results of the gyrified structure of Au-PDMS reticular-like nanophases.

FIGS. 4A to 4F show the analysis results of the excellent strain-invariant electrical conductivity achieved through the 3D nanophase structure of Au-PDMS.

FIGS. 5A to 5G display the analysis results of the stability of Au-PDMS nanophase 3D structures in a multimodal (multi-modal) setting.

### DETAILED DESCRIPTION OF THE DISCLOSURE

The embodiments of the present invention will now be described in detail with reference to the accompanying drawings and the descriptions contained therein. However, the present invention is not limited or restricted by these embodiments.

The terms used in this specification are intended to describe the embodiments and are not meant to limit the invention. Unless explicitly stated otherwise, the singular forms used in this specification include the plural as well.

The terms “comprises” and/or “comprising,” as used herein, do not exclude the presence or addition of one or more other components, steps, operations, and/or elements beyond those specifically mentioned.

The terms “embodiment,” “example,” “aspect,” and “illustration,” as used herein, are not intended to imply that any particular feature or design is preferred or advantageous over others.

Additionally, the term “or,” as used herein, means an inclusive logical “or” rather than an exclusive logical “or,” unless otherwise specified or clearly understood from the context. For example, the expression “x uses a or b” means any of the natural inclusive permutations of “a” or “b.”

Furthermore, the singular terms “a” or “an,” as used in the specification and claims, should generally be interpreted as meaning “one or more,” unless otherwise specified or clearly indicated by the context.

Moreover, when a film, layer, region, or component is described as being “on” or “over” another part, it includes not only cases where it is directly on top of the other part but also cases where another film, layer, region, or component is interposed in between.

Metals and elastomers are thermodynamically incompatible materials that do not mix well. Therefore, hybridizing them physically and chemically to form a composite is a challenging task. Even when a composite of metal and elastomer is successfully fabricated, there is a high likelihood of deterioration in the excellent electrical conductivity of the metal or the superior elastic recovery and stretchability of the elastomer.

To address this issue, the present invention aims to provide a composite in which the properties of the metal and elastomer are preserved before mixing, thus exhibiting all their respective characteristics while achieving physical and chemical hybridization of the two materials.

To this end, by varying the crosslinking ratio of the elastomer and the deposition thickness of the metal, the following three dynamics of the related processes can be controlled: Migration of excess crosslinker, Deposition of metal atoms onto the interconnected elastomer nanostructure, and Growth of the elastomer nanostructure with deposited metal atoms and the formation of a nanophase composite.

The method for manufacturing a gyrified metal-elastomer composite according to the present invention includes: step S100 of mixing a prepolymer and a crosslinker to form an elastomer; step S200 of depositing a metal onto the elastomer to form a metal-elastomer composite with the metal embedded in the elastomer; and step S300 of self-forming gyrifications on the metal-elastomer composite. The elastomer may be a reticular elastomer.

The metal used in this process may be any one selected from the group consisting of gold Au, silver Ag, copper Cu, iron Fe, nickel Ni, manganese Mn, tin Sn, zinc Zn, aluminum Al, magnesium Mg, and titanium Ti. However, the metal material is not necessarily limited to these.

The elastomer used in this process may be any one selected from the group consisting of polydimethylsiloxane (PDMS), ecoflex, silicone rubber, fluoro silicone rubber, vinyl methyl silicone rubber, styrene-butadiene-styrene (SBS) block copolymer, styrene-ethylene-butylenestyrene (SEBS) block copolymer, styrene-isoprene-styrene (SIS) block copolymer, styrene-butadiene rubber (SBR), butadiene rubber (BR), isobutylene-isoprene rubber (IIR), ethylene propylene rubber (EPR), ethylene-propylene-diene monomer rubber (EPDM), isoprene rubber (IR), isobutylene rubber (IR), acryl rubber, acrylonitrile-butadiene rubber (ABR), polyurethane, polyether urethane rubber, polyester urethane, epichlorohydrin rubber, and polychloroprene rubber.

However, the material for the elastomer is not necessarily limited to these. As long as the material is stretchable and capable of forming a gyrified structure on its surface, there are no specific restrictions.

Hereinafter, the step S100 of forming an elastomer by mixing a prepolymer and a crosslinker will be described in detail. The prepolymer and the crosslinker refer to the prepolymer and crosslinker of the elastomer, respectively, and are components of the elastomer that can form a reticular elastomer when mixed.

In the step S100 of forming the elastomer, when the prepolymer and the crosslinker are mixed at a specific ratio, a metal-elastomer composite in which metal is embedded within the elastomer can be formed, satisfying the conditions for self-forming gyrifications on the metal-elastomer composite. Detailed information on the ratio of the prepolymer to the crosslinker will be discussed later in conjunction with the metal deposition rate in step S200.

Hereinafter, the step S200 of forming a metal-elastomer composite by depositing metal onto the elastomer, with the metal embedded in the elastomer, will be described in detail.

The metal may be deposited by any one method selected from Physical Vapor Deposition (PVD), Chemical Vapor Deposition (CVD), and Atomic Layer Deposition (ΔLD), but is not limited thereto.

For example, when using the Physical Vapor Deposition (PVD), the metal may be vaporized in the form of metal atoms. In this case, it is preferable to use thermal evaporation, which is a type of Physical Vapor Deposition.

According to one embodiment, the step S200 of forming the metal-elastomer composite may include:

A step S210 in which the elastomer and the metal bond at the nanoscale, and a step S220 in which the metal grows in the z-axis direction (a direction perpendicular to the elastomer) within the elastomer.

According to one embodiment, the step S200 of forming the metal-elastomer composite may include: step S210, where the metal penetrates the pores of the elastomer; and step S220, where the metal grows in the z-axis direction (perpendicular to the elastomer).

In step S220, based on these nuclei, the metal crystals grow, and the metal nanoparticles gradually evolve into metal nanorods and eventually into metal nanoneedles.

The deposition rate of the metal, like the ratio of the prepolymer to the crosslinker, must have a specific value to form a metal-elastomer composite where the metal is embedded in the elastomer, satisfying the conditions for the self-formation of gyrifications in the metal-elastomer composite.

Regarding the deposition rate of the metal, the deposition thickness (d) of the metal, as measured by a quartz crystal microbalance in the deposition chamber, can be considered the product of the process time (t_{process}) and the deposition rate (Å/s). This parameter is used to control the total amount of deposited metal atoms.

[Section 1] According to one embodiment, when the prepolymer and crosslinker are mixed at a weight ratio of 5:1 to 10:1, the deposited metal thickness may range from 7.5 nm to 12.5 nm.

[Section 2] Alternatively, when the prepolymer and crosslinker are mixed at a weight ratio of 3.5:1 to 5:1, the deposited metal thickness may range from 12.5 nm to 37.5 nm.

[Section 3] Alternatively, when the prepolymer and crosslinker are mixed at a weight ratio of 3:1 to 4:1, the deposited metal thickness may range from 37.5 nm to 87.5 nm.

[Section 4] Alternatively, when the prepolymer and crosslinker are mixed at a weight ratio of 3:1 to 3.5:1, the deposited metal thickness may range from 87.5 nm to 125 nm.

[Section 5] Alternatively, when the prepolymer and crosslinker are mixed at a weight ratio of 2.5:1 to 3.5:1, the deposited metal thickness may range from 125 nm to 250 nm.

Preferably, when the prepolymer and crosslinker are mixed at a weight ratio of 3:1 to 3.5:1, the deposited metal thickness may range from 87.5 nm to 125 nm.

By adjusting the ratio of prepolymer to crosslinker (P), the crosslink density of the resulting elastomer can be controlled. When the ratio (P) is within the above range, the deposited metal can grow into metal nanoparticles and metal nanoneedles, subsequently forming a metal reticular structure connected in a network, thereby creating a composite with the elastomer.

In this specification, such a metal-elastomer composite with the metal embedded in the elastomer is referred to as having a “nanophase.” Specifically, a metal-elastomer composite with a nanophase indicates a state where thermodynamically immiscible metal and elastomer materials are nanoblended, meaning that the metal and elastomer are mixed at the nanoscale to achieve a stable phase. A characteristic of nanophase composites is that not only are two or more different materials physically and chemically mixed, but also the performance of the individual materials forming the nanophase composite is preserved without degradation.

Meanwhile, if the ratio (P) of the prepolymer to the crosslinker exceeds the above range, the mixing ratio of the crosslinker becomes too low, reducing the migration of excess crosslinker. As a result, the formation of a reticular metal structure is restricted, which affects the mobility of metal atoms and the deposition process. Consequently, the metal is more likely to grow in the form of continuous thin films within the elastomer.

On the other hand, if the ratio (q) of the prepolymer to the crosslinker is below the above range, the mixing ratio of the crosslinker becomes too high, increasing the migration of excess crosslinker and inducing the formation of a reticular metal structure. As a result, metal crystal growth is restricted, and the metal is more likely to be deposited in the form of particles.

The metal-elastomer nanophase composite is spontaneously formed as the metal is physically vapor-deposited onto the exposed surface of the elastomer within a vacuum chamber. This process can be facilitated by the migration of excess crosslinker from the bulk material of the elastomer to its surface.

From the perspective of growth dynamics, the formation of the nanophase can be categorized into three cases based on the competition between the flux of excess crosslinker migration (J_{migration}) and the flux of metal deposition (J_{deposition}).

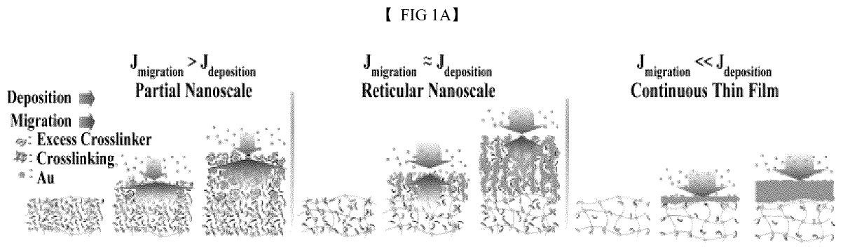

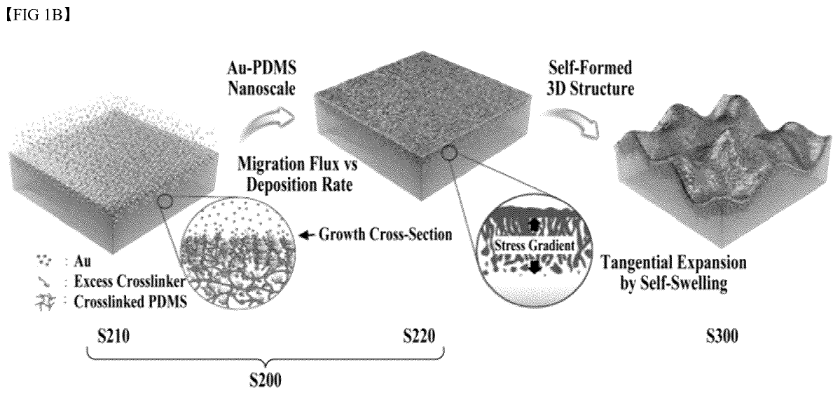

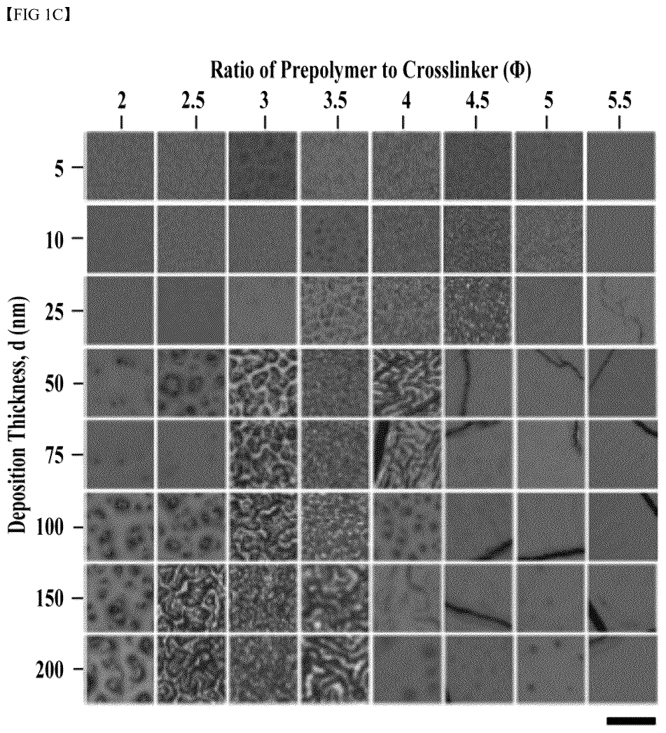

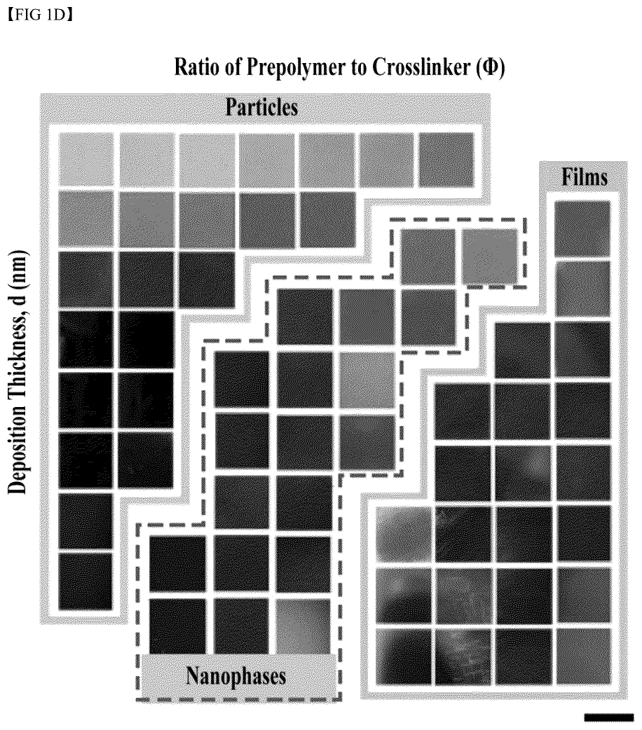

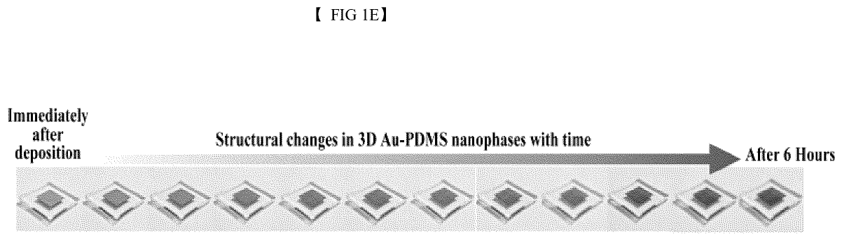

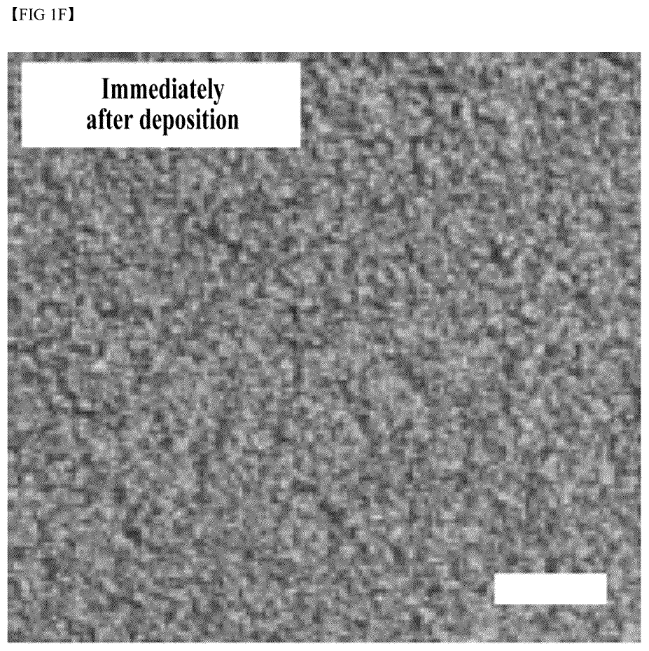

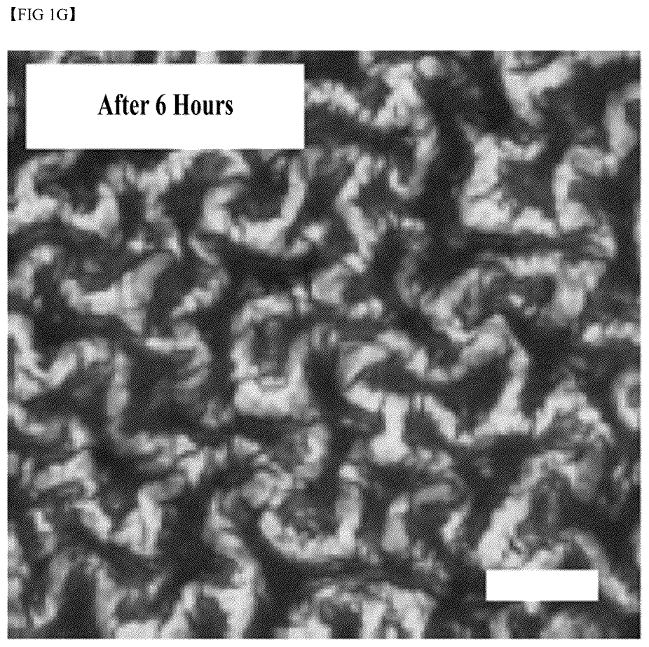

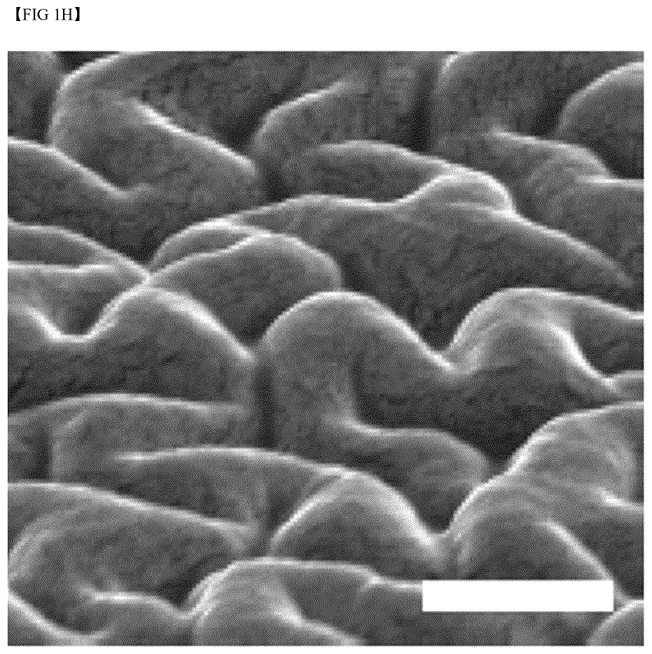

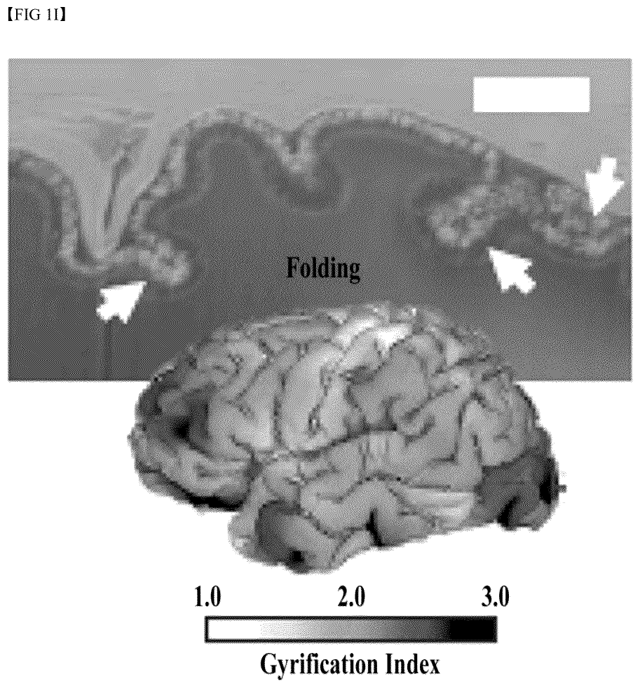

In this regard, a schematic diagram illustrating the mechanism by which various structures of the metal-elastomer composite are formed is shown in FIG. 1A.

Referring to FIG. 1A, the first case occurs when the flux of excess crosslinker migration significantly exceeds the flux of metal deposition (J_{migration}>J_{deposition}). This situation arises under the following conditions: The metal nanoparticles become fully encapsulated by the rapidly migrating excess crosslinker. During the process of metal crystal growth, the encapsulated metal nanoparticles undergo structural influences, making them more likely to remain as individual nanoparticles rather than forming continuous metal structures.

The second case occurs when the flux of excess crosslinker migration is similar to the flux of metal deposition (J_{migration}=J_{deposition}). In this scenario, the excess crosslinker is unable to fully cover the metal nanoparticles initially due to a limited migration time. As a result, the metal nanoparticles act as nuclei, enabling the anisotropic growth of metal crystals. In other words, the synchronization of the migration flux of the crosslinker and the deposition flux of the metal is a key factor in forming a reticular nanophase metal-elastomer composite.

The third case occurs when the flux of metal deposition significantly exceeds the flux of excess crosslinker migration (J_{migration}<<J_{deposition}). In contrast to the first case, the rapid rate of metal deposition reduces the likelihood of forming metal nanophases, and instead, the formation of a metal thin film becomes more likely.

The metal-elastomer composite generated through step S200 may have metal embedded in the upper surface of the elastomer. In other words, while it may appear that the metal exists as a thin film on the elastomer's surface, in reality, the metal thin film is not independently deposited on the elastomer. Instead, the elastomer and metal are chemically bonded at the nanoscale.

When metal atoms are deposited onto the elastomer, various structures and phases can emerge, ranging from a liquid-like (non-crosslinked) composite to a solid slab (fully crosslinked) depending on the degree of crosslinking between the metal and the elastomer. Even solid slabs that appear identical may have different crosslinked networks, and molecular dynamics can vary significantly depending on the amount of excess mobile molecules.

Furthermore, the mixing ratio of the prepolymer is closely related to the migration flux of the excess crosslinker.

On the other hand, if the metal is not crosslinked with the elastomer and instead exists as a thin film on the upper surface of the elastomer, the metal thin film is likely to separate from the elastomer during processes that apply various strains to the metal-elastomer composite.

Therefore, in such a structure where the metal thin film is deposited on the elastomer, additional treatment is required to prevent the metal thin film from detaching from the elastomer. This structure also has limitations in its applicability to devices involving deformation, such as flexible or stretchable devices.

The metal-elastomer composite of the present invention enables the control of metal growth and gyrification structure formation by regulating the migration of excess crosslinker and the aggregation of metal atoms through adjustments in the mixing ratio of the prepolymer and crosslinker for elastomer preparation and by controlling the metal deposition rate.

In other words, by controlling the dynamic interactions between the metal atoms and the elastomer, a metal-elastomer composite can be fabricated in which the metal is embedded within the elastomer, more specifically, embedded in the upper layer of the elastomer.

Hereinafter, the step S300 of self-forming gyrifications on the metal-elastomer composite will be described in detail.

In step S300, where gyrifications self-form on the metal-elastomer composite, the composite can spontaneously deform into a three-dimensional structure. In other words, the metal-elastomer composite according to the present invention does not involve forming a gyrified structure by processing the elastomer before metal deposition or by processing the metal-deposited elastomer. Instead, the gyrified structure can self-form over time by simply leaving the metal-elastomer composite as is.

During this process, the gyrified structure can be formed through nanoscale three-dimensional morphological changes. That is, in step S200, metal atoms grow within the elastomer, and during this growth process, a mismatch in the elastic modulus between the metal and the elastomer generates intrinsic stress. In step S300, the elastomer releases this stress, allowing the formation of self-induced gyrifications.

In other words, the metal-elastomer composite in a quasi-stable physical state generates internal stress due to the presence of metal nanoneedles. The elastomer undergoes structural evolution to counteract this stress, eventually relieving the stress and reaching a physically stable state.

In this specification, this process of structural evolution is referred to as “gyrification” to distinguish it from general wrinkling or buckling. The term “gyrification” originally describes the folding phenomenon of the cerebral cortex. Unlike conventional gyrifications or buckles formed using external forces, such as pre-stretching the elastomer substrate before mixing with metal, the gyrified metal-elastomer composite of the present invention exhibits a convoluted three-dimensional gyrification structure that closely resembles the folds of the cerebral cortex.

According to one embodiment, the step S300 of self-forming gyrifications on the metal-elastomer composite can be performed for 0.5 to 36 hours, preferably for 6 hours. This step can be carried out by allowing the metal-elastomer composite to cool in ambient air and at room temperature (15° C. to 35° C.).

If the step is performed for less than 0.5 hours, the gyrifications on the metal-elastomer composite may not form sufficiently. Conversely, if it is performed for more than 36 hours, it may result in unnecessary time consumption.

FIG. 1B is a schematic diagram of a gyrified metal-elastomer composite (gyrified Au-PDMS composite) that is self-formed through the deposition of vaporized metal (Au) onto an elastomer (PDMS substrate).

Referring to step S210 in FIG. 1B, A crosslinked reticular elastomer (PDMS) is formed due to the crosslinker, and vaporized metal (Au) atoms settle on its surface while bonding within the reticular elastomer (PDMS). The metal (Au) atoms grow and are deposited in a direction perpendicular to the elastomer (PDMS).

In step S220, a stress gradient is formed in the z-axis direction due to the integrated metal (Au). In step S300, the elastomer (PDMS) undergoes self-swelling in response to the z-axis directional stress relief, leading to tangential expansion.

As a result, the upper layer of the deposited metal (Au) within the elastomer (PDMS) undergoes differential tangential stress, ultimately forming a 3D gyrified structure.

The gyrified metal-elastomer composite according to the present invention is manufactured using the method for producing the gyrified metal-elastomer composite described herein. More specifically, the gyrified metal-elastomer composite is formed with metal embedded within the elastomer, featuring a structure in which nanoscale three-dimensional gyrifications are formed at the interface where the metal contacts the elastomer.

The gyrified metal-elastomer composite may have metal embedded in the upper surface of the elastomer, with a structure in which three-dimensional gyrifications are formed on the surface of the elastomer. Furthermore, the gyrifications of the gyrified metal-elastomer composite may have a gyrified structure.

According to one embodiment, the gyrified metal-elastomer composite may have the elastomer and metal chemically bonded at the nanoscale. “Chemically bonded at the nanoscale” specifically refers to metal nanostructures with sizes ranging from 1 nm to 500 nm formed within the elastomer. In other words, the metal embedded in the elastomer is chemically bonded at the nanoscale, forming a nanophase structure.

According to one embodiment, the thickness of the metal in the gyrified metal-elastomer composite may range from 10 nm to 10,000 nm. Preferably, the thickness of the metal in the gyrified metal-elastomer composite may range from 75 nm to 150 nm, wherein the thickness of the metal includes all parts deposited onto the elastomer within the gyrified metal-elastomer composite.

The metal-elastomer composite possesses a tangential stress gradient due to the nanophase, which imparts the elasticity and ductility necessary for nanoscale folding. In contrast to the gyrified metal-elastomer composite, which exists as an inseparable single layer, a bilayer structure where the metal layer exists as a thin film on top of the elastomer layer can only form a buckled configuration. This is due to the high energy cost associated with nanoscale wrinkling of the metal layer, making it incapable of undergoing gyrification.

Additionally, the soft elastomer layer beneath the harder metal layer is insufficient to induce the stress required to fold the metal layer. While a bilayer structure may bend to form mesoscopic wave-like patterns, achieving nanoscale folding is challenging because the rigidity of the metal layer increases exponentially with structural changes.

Specifically, gyrification can only be observed when the elastic modulus ratio between the two materials in the composite (E̅_̅{̅P̅D̅M̅S̅}̅/3E̅ₘ̅ₑ̅ₜ̅ₐ̅ₗ̅) is high enough to create large amplitudes but not so high as to result in excessively low density. A representative example is the human brain, which can be considered analogous to a rubber-rubber composite with similar elastic moduli.

Hereinafter, the conductivity akin to metal and the stretchability akin to elastomer in the gyrified metal-elastomer composite will be described.

Depending on the application, electrodes can generally be classified into two types: active electrodes and passive electrodes. Active electrodes are used to directly inject or extract current into or from a system, whereas passive electrodes function to transfer current between various components or parts of a circuit. Among these, the strain-invariant electrical properties of the embodiments of the present invention are particularly significant for passive bus lines, ensuring stable and reliable conductive pathways within and between circuit elements.

When uniaxial strain or areal strain is applied, the nanophase composite can exhibit strain-invariant resistance, meaning that the resistance remains unchanged despite the applied strain. The characteristics of the gyrified metal-elastomer composite, which exhibit less resistance variation under strain compared to ideal elastic conductors, are primarily attributed to the unique stretchability of the reticular nanophase and the three-dimensional expansion properties of the externally gyrified structure.

This combination of intrinsic and external properties provides high adhesion, structural and electrical elasticity, which are essential to prevent delamination and degradation of electrical conductivity in the composite material. This is supported by the high gyrification index of 1.75 calculated in embodiment section 4, defined as the ratio of the actual surface area to the projected area in FIG. 1i.

The reason the gyrified metal-elastomer composite exhibits strain-invariant electrical conductivity is that, during the stretching process of the metal-elastomer nanophase, the three-dimensional cerebral cortex-like gyrified structure unfolds. In other words, while the gyrifications are unfolding, the metal-elastomer nanophase does not stretch, preventing cracks from forming until the gyrifications are completely flattened. Consequently, stretching the metal-elastomer nanophase does not affect its conductivity.

This property makes it suitable for fabricating stretchable devices.

As described above, in the gyrified metal-elastomer composite, cracks do not form until the gyrifications are fully unfolded, even when strain is applied. This allows the composite to maintain the inherently high electrical conductivity of the metal.

According to one embodiment, the electrical conductivity of the gyrified metal-elastomer composite may range from 1.0×10² S/cm to 1.0×10⁶ S/cm under an areal strain of 100% to 156%. Here, areal strain refers to the application of strain to an object in the shape of a sphere, which stretches the object in three dimensions. In contrast, applying biaxial strain stretches the object only within a two-dimensional plane, making it more limited.

The areal strain is calculated as the percentage ratio of the area of the stretched gyrified metal-elastomer composite to the area of the initial gyrified metal-elastomer composite before the strain is applied.

Hereinafter, the environmental durability of gyrified Au-PDMS nanophases for soft electronics will be discussed.

Based on the electrical and mechanical properties of our reticular Au-PDMS nanophase sample, which mimics the gyrified structure of the cerebral cortex, it demonstrates versatile performance suitable for application in environmentally resilient soft electronics. Our sample exhibits excellent stability against pH variations, chemical and thermal exposure, as well as mechanical wear.

According to one embodiment, the gyrified metal-elastomer composite may exhibit electrical conductivity ranging from 1.0×10² S/cm to 1.0×10⁶ S/cm in solutions with pH values ranging from 2 to 13. Even under such harsh pH conditions, the gyrified metal-elastomer composite maintains exceptional durability and retains its initial electrical conductivity, making it applicable to various environmental conditions.

Additionally, the Au-PDMS nanophase with a cerebral cortex-like gyrified structure is well-suited for application in lithography processes, and the Au-PDMS nanophase sample can be washed using detergents and washing machines without any loss of conductivity.

These properties enable the stretchable conductive film to perform repetitive and stable operations in wearable electronics, including military and medical applications, and to be utilized in the production of functional devices fabricated using lithographic techniques.

In other words, the 3D structure of the Au-PDMS nanophase is highly suitable for application as a stretchable conductive film in soft electronics. It can be extensively used across various fields, including biophysical monitoring within the gastrointestinal tract, multimodal implantable devices such as ocular prosthetics, soft robotics employing mechanical strain-gated logic circuits, and functional fabrics for space exploration.

Hereinafter, the present invention will be described in greater detail through embodiments. These embodiments are provided to explain the invention more specifically and are not intended to limit the scope of the invention to these embodiments.

### [Examples and Comparative Examples] Gyrified Au-PDMS Composite

Two components of PDMS, namely PDMS prepolymer and PDMS crosslinker (Sylgard 184, Dow Corning), were prepared.

According to the Material Safety Data Sheet (MSDS) for the PDMS prepolymer, it contains 0.5 wt % xylene, 0.2 wt % ethylbenzene, >60 wt % dimethylvinyl-terminated dimethylsiloxane, 30-60 wt % dimethylvinylated silica and trimethylated silica, and 1-5 wt % tetra(trimethylsiloxy) silane.

According to the MSDS for the PDMS crosslinker (curing agent) Sylgard 184, it contains 0.19 wt % xylene, <0.1 wt % ethylbenzene, 55-75 wt % dimethyl, methylhydrosiloxane, 15-35 wt % dimethylvinyl-terminated dimethylsiloxane, 10-30 wt % dimethylvinylated silica and trimethylated silica, and 1-5 wt % tetramethyl tetravinyl cyclotetrasiloxane. Additionally, a platinum-containing siloxane complex, which is expected to play a critical role in crosslinking, may be present as a catalyst in the curing agent.

The PDMS prepolymer and PDMS crosslinker were mixed at various ratios (Φ=2-20). The composite was then thermally cured at 80° C. for 4 hours. The resulting PDMS was attached to the sample holder inside a physical vapor deposition chamber manufactured by INFOVION. To prevent the evaporation of low-molecular-weight substances within the PDMS, a consistent vacuum pressure was maintained for all samples.

Au (99.9999%) was deposited onto the PDMS at room temperature using thermal evaporation under a constant pressure of 1.0× 10⁻⁶ Torr and at various deposition rates (0.5 Å/s to 10 Å/s). The in-situ deposition rate and deposition amount were monitored using a quartz crystal microbalance. The Au deposition thickness ranged from 5 nm to 200 nm depending on the deposition rate, with a deposition thickness of 100 nm achieved at an Au deposition rate of 2.5 Å/s.

The Au deposition consisted of two stages. A pre-deposition stage was conducted for 1 minute with the shutter closed, followed by the main deposition stage, where the shutter was opened, lasting for 400 seconds to form the Au-PDMS composite.

After the deposition was completed, the samples were immediately removed from the chamber and aged in ambient air for 6 hours to form the gyrified Au-PDMS composite.

Various examples and comparative examples prepared with different weight ratios (Φ) of crosslinker to prepolymer and various Au deposition thicknesses (d) were manufactured as shown in Table 1 below.

TABLE 1

| | | | Weight ratio of prepolymer to crosslinker (Φ) | | | | | | | |
|---|---|---|---|---|---|---|---|---|---|---|
| | | | 2 times | 2.5 times | 3 times | 3.5 times | 4 times | 5 times | 10 times | 20 times |
| Au | 5 | nm | Comparative | Comparative | Comparative | Comparative | Comparative | Comparative | Comparative | Comparative |
| deposition | | | Example | Example | Example | Example | Example | Example | Example | Example |
| thickness | | | 1-1 | 1-2 | 1-3 | 1-4 | 1-5 | 1-6 | 1-7 | 1-8 |
| (d) | 10 | nm | Comparative | Comparative | Comparative | Comparative | Comparative | Example | Example | Comparative |
| | | | Example | Example | Example | Example | Example | 1-1 | 1-2 | Example |
| | | | 2-1 | 2-2 | 2-3 | 2-4 | 2-5 | | | 2-6 |
| | 25 | nm | Comparative | Comparative | Comparative | Example | Example | Example | Comparative | Comparative |
| | | | Example | Example | Example | 2-1 | 2-2 | 2-3 | Example | Example |
| | | | 3-1 | 3-2 | 3-3 | | | | 3-4 | 3-5 |
| | 50 | nm | Comparative | Comparative | Example | Example | Example | Comparative | Comparative | Comparative |
| | | | Example | Example | 3-1 | 3-2 | 3-3 | Example | Example | Example |
| | | | 4-1 | 4-2 | | | | 4-3 | 4-4 | 4-5 |
| | 75 | nm | Comparative | Comparative | Example | Example | Example | Comparative | Comparative | Comparative |
| | | | Example | Example | 4-1 | 4-2 | 4-3 | Example | Example | Example |
| | | | 5-1 | 5-2 | | | | 5-3 | 5-4 | 5-5 |
| | 100 | nm | Comparative | Comparative | Example | Example | Comparative | Comparative | Comparative | Comparative |
| | | | Example | Example | 5-1 | 5-2 | Example | Example | Example | Example |
| | | | 6-1 | 6-2 | | | 6-3 | 6-4 | 6-5 | 6-6 |
| | 150 | nm | Comparative | Example | Example | Example | Comparative | Comparative | Comparative | Comparative |
| | | | Example | 6-1 | 6-2 | 6-3 | Example | Example | Example | Example |
| | | | 7-1 | | | | 7-2 | 7-3 | 7-4 | 7-5 |
| | 200 | nm | Comparative | Example | Example | Example | Comparative | Comparative | Comparative | Comparative |

| | | | | | | | |
|---|---|---|---|---|---|---|---|
| Example | 7-1 | 7-2 | 7-3 | Example | Example | Example | Example |
| 8-1 | | | | 8-2 | 8-3 | 8-4 | 8-5 |

### [Experimental Example 1] Analysis of Gyrification Structures in Gyrified Au-PDMS Composites

FIG. 1C shows images of surface morphologies of Comparative Examples 1-1 to 8-5 and Examples 1-1 to 7-3 based on various prepolymer mixing ratios (q) and metal deposition thicknesses (d) (scale bar: 150 μm). Observations of surface variations using optical microscopy and transmission electron microscopy confirmed that the nanostructure morphology, ranging from nanoparticles and nanofilms to complex 3D structures, can indeed be controlled and formed.

FIG. 1D presents photographic images showing the color variations of Comparative Examples 1-1 to 8-5 and Examples 1-1 to 7-3 under different prepolymer mixing ratios (q) and metal deposition thicknesses (d) (scale bar: 1 cm). The arrangement of the Au-PDMS composites in FIG. 1D is identical to that in FIG. 1c. Referring to FIG. 1D, the Au-PDMS composites were observed in three distinct nanostructures: “particles,” “3D nanophases,” and “continuous films.” The structural diversity identified in FIG. 1C is attributed to variations in Au nanostructures, which can be clearly verified through plasmonic color changes.

As shown in FIG. 1D, when the prepolymer mixing ratio (q) is less than three times that of the crosslinker, nanoparticles tend to form on the PDMS substrate regardless of the metal deposition thickness (d). Conversely, when the prepolymer mixing ratio (P) exceeds ten times that of the crosslinker, continuous metal films are formed. When the prepolymer mixing ratio (q) falls between these two extremes, 3D nanophases are observed, exhibiting structural variations ranging from elongated nanoparticles and nanoneedles to reticular structures.

Additionally, as the prepolymer mixing ratio (q) increases, densification of the metal into the PDMS can be observed. Conversely, as the prepolymer mixing ratio (q) decreases, the increase in the crosslinker content strengthens the tendency of the metal-elastomer composite to form nanophases.

FIG. 1E is an image capturing the spontaneous gyrifications formed over time during 6 hours after Au deposition in section 4 (PDMS length: 10 mm, metal rectangle length: 5 mm). Referring to FIG. 1E, it can be observed that the color of the example changes with the evolution of the 3D structure. Before the gyrifications are formed, the surface of the Au-PDMS composite exhibits the gold color of Au. However, as time progresses and 3D gyrifications form, alternating raised and indented regions appear. The shadows created by the indented regions cause the overall color to gradually darken.

This is supported by FIGS. 1F and 1G. FIG. 1F shows an optical microscope image of the Au-PDMS composite shortly after Au deposition, while FIG. 1G shows an optical microscope image of the gyrified Au-PDMS composite 6 hours after Au deposition (scale bar: 150 μm).

FIG. 1H is a tilted SEM image of section 4 (scale bar: 5 μm), showing a structure highly similar to the gyrified folds of the cerebral cortex.

FIG. 1I is a cross-sectional SEM image of section 4, with white arrows indicating the folds resulting from the structural expansion of the elastomer (scale bar: 1 μm). The illustration of the human brain within FIG. 1I is provided as an example resembling the three-dimensional gyrified structure of the gyrified Au-PDMS composite, along with the estimated local gyrification index (GI) from the human brain.

### [Experimental Example 2] Analysis of the Growth Dynamics of Au-PDMS Composites Controlled by Chemical Kinetics

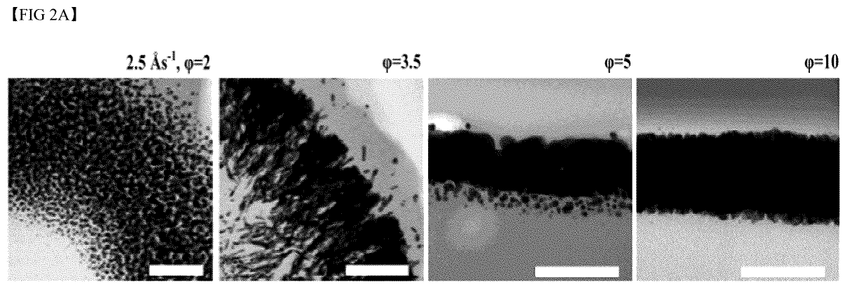

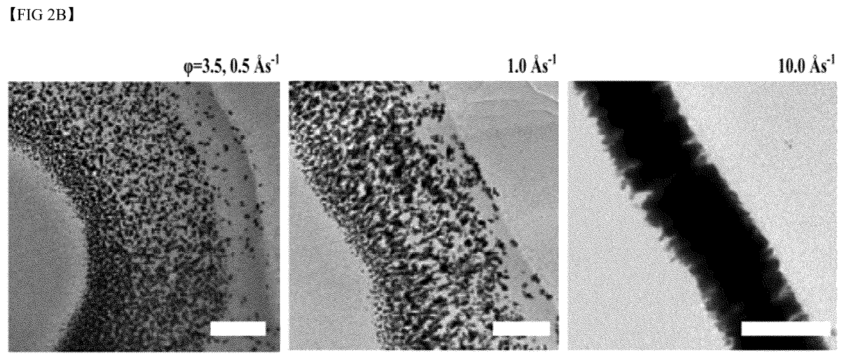

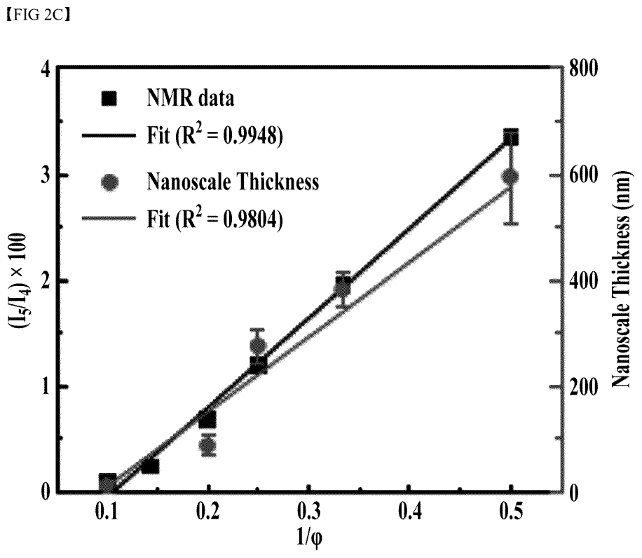

FIG. 2A shows cross-sectional HRTEM images of gyrified Au-PDMS composites from Comparative Examples 6-1, 6-4, 6-5, and Example 5-2 (deposition rate: 2.5 Å/s, Ø=2, 3.5, 5, and 10, respectively).

Referring to FIG. 2A, In Comparative Example 6-1, Au appears in particle form, while in Comparative Examples 6-4 and 6-5, Au appears in thin film form. In contrast, Example 5-2 (2.5 Å/s, Φ=3.5) shows a nanostructure of Au-PDMS, formed through interconnection and bonding.

FIG. 2B shows cross-sectional HRTEM images of gyrified Au-PDMS composites from Comparative Example 1-4 and Example 7-3 (Φ=3.5, deposition rates: 0.5, 1.0, and 10.0 Å/s, respectively) (scale bar: 200 nm).

Referring to FIG. 2B, In Comparative Example 1-4, Au appears in particle form, whereas in Example 7-3, it forms a nanostructure of Au-PDMS, created through interconnection and bonding.

To analyze the formation dynamics of the three-dimensional nanophases in the Au-PDMS composite, the parameter Φ was adjusted to manipulate the flux of Au atoms introduced into the PDMS. This allowed observation of the interaction and competition between the migration flux of excess crosslinker and the deposition flux of Au atoms.

The cross-sectional high-resolution TEM (HRTEM) images in FIGS. 2A and 2B clearly demonstrate that the nanophase morphology is governed by the relative flux differences between the excess crosslinker and Au deposition. These results suggest that, in terms of growth dynamics, nanophases can be categorized into three distinct cases based on the competition between the migration flux of excess crosslinker (J_{migration}) and the deposition flux of Au (J_{deposition}).

FIG. 2C is a graph showing the relationship between the peak intensity ratio of Si—H to Si—CH3 obtained from the ¹H NMR spectrum and 1/Φ.

According to FIG. 2C, a negative correlation was observed between the prepolymer mixing ratio (Φ) and the thickness of the Au nanophase. This supports the relationship in which the thickness of the Au nanophase increases as the prepolymer mixing ratio (Φ) decreases, i.e., as the migration of the crosslinker increases.

### [Experimental Example 3] Gyrification Mechanism of Au-PDMS Composite

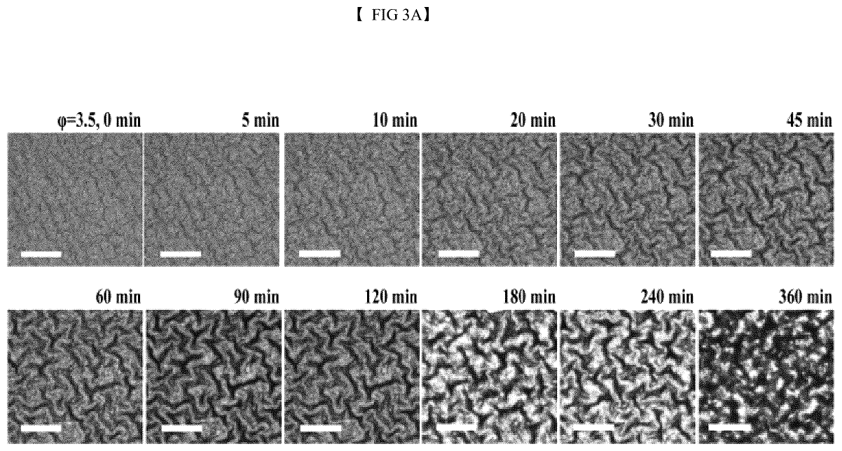

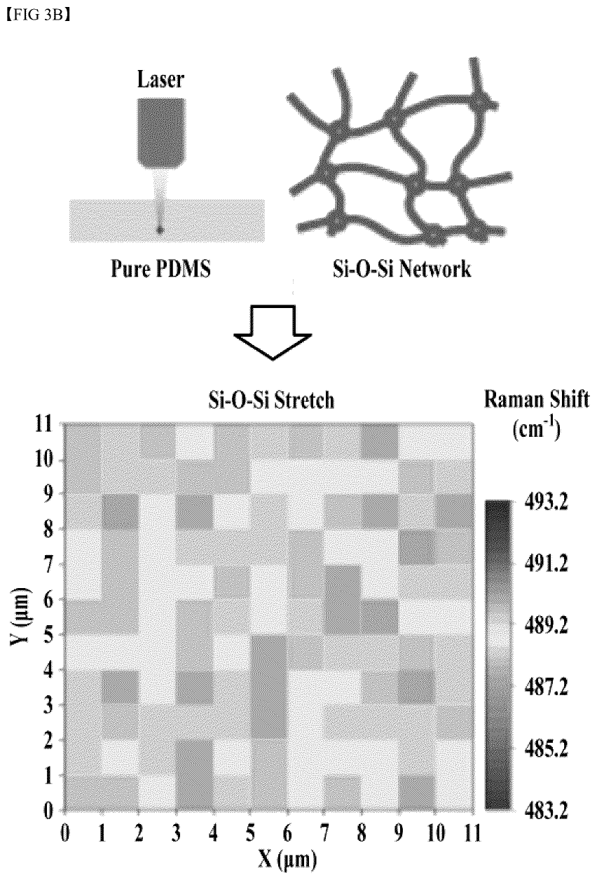

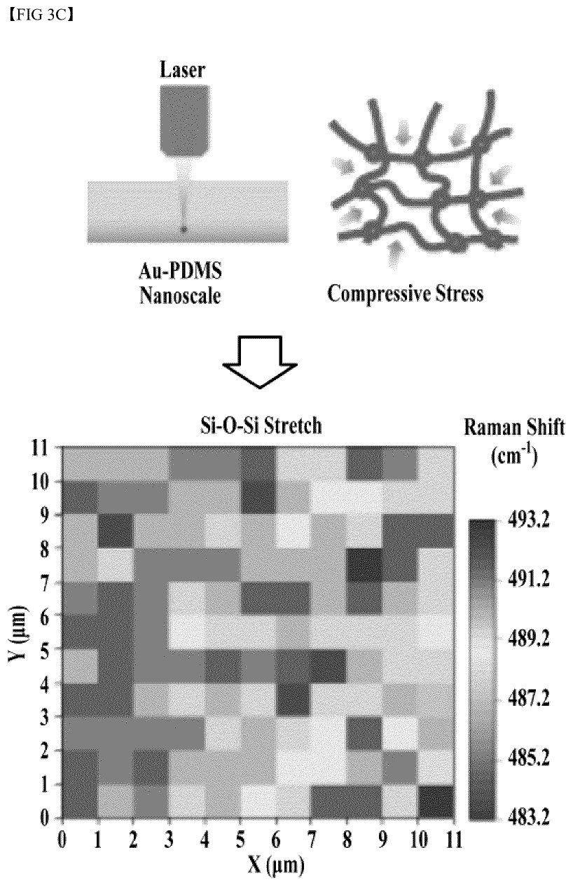

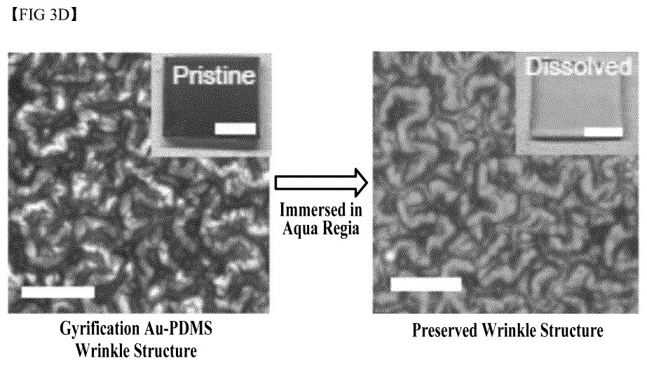

FIG. 3A is an optical microscope image showing the spontaneous gyrification of the Au-PDMS composite in Example 5-2 over 6 hours after deposition (scale bar: 15 μm). It can be observed that the gyrified structure begins to form immediately after deposition and develops into deep and large grooves at the micrometer scale over 6 hours.

The spontaneous gyrification process, occurring within a few hours, is one of the most distinctive aspects of the Au-PDMS composite, setting it apart from typical gyrification or buckle structures.

The formation of these microstructures is attributed to residual compressive stress within the nanophase. To verify the residual compressive stress accumulated at the interface between the Au-PDMS nanophase and the bulk PDMS, spatially resolved Raman spectroscopy was performed, and Raman mapping images of PDMS before Au deposition (FIG. 3B) and PDMS after Au deposition, where the stress had not yet been relaxed (FIG. 3C), were compared.

After Au deposition, the Raman peak associated with Si—O—Si stretching in PDMS (490.8 cm⁻¹) exhibited a redshift of 5 cm⁻¹, indicating significant spatial deformation in the PDMS adjacent to the Au layer.

FIG. 3D shows optical microscope images of the gyrified Au-PDMS composite nanophase before and after dissolution in aqua regia (scale bar: 15 μm). The inset photographic images display the distinct color changes caused by the dissolution of Au (scale bar: 1 cm). Referring to FIG. 3D, it can be observed that although the gold was dissolved by the aqua regia, the gyrified structure remained intact and unchanged.

### [Experimental Example 4] Measurement of Strain-Invariant Electrical Conductivity

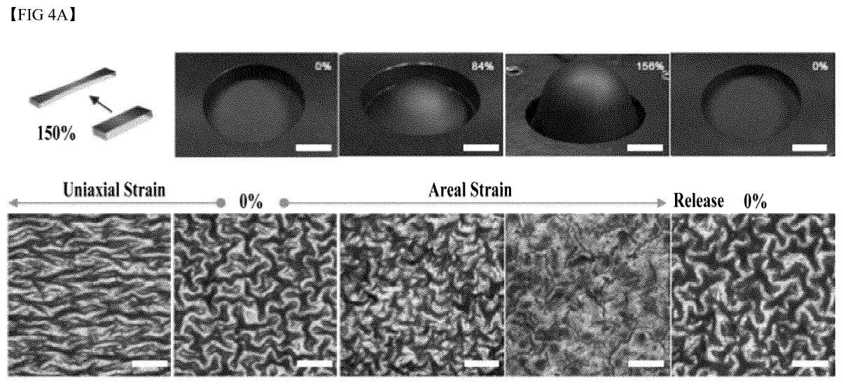

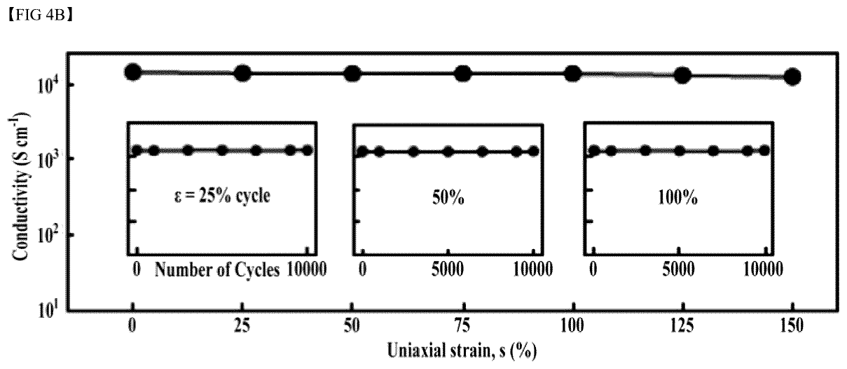

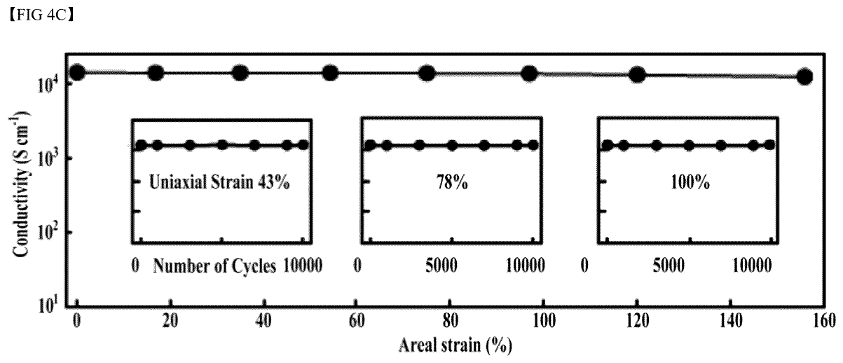

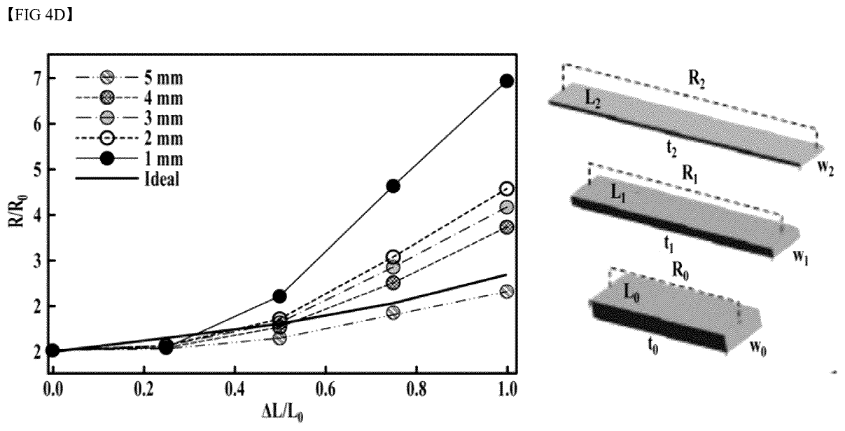

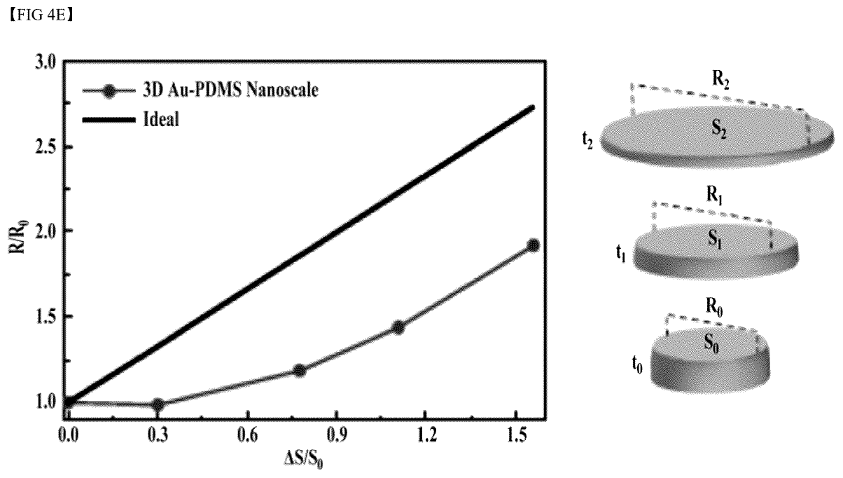

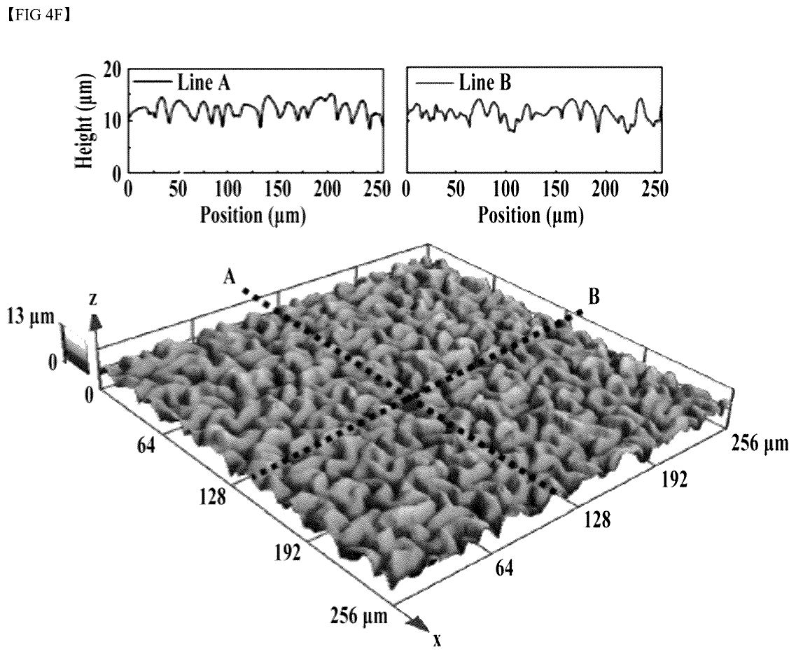

FIG. 4A illustrates strain release due to the gyrified elastomer structure combined with the Au-PDMS nanophase in section 4 under uniaxial strain (left) and areal strain (right). The images include optical microscope images (bottom, scale bar: 1 cm) and photographic images (top, scale bar: 150 μm). The strain-release image at 0% strain (far right) demonstrates the reversibility of the example.

FIG. 4B is a graph showing electrical conductivity of 1.4×10⁴S/cm under uniaxial strain up to 150%, while FIG. 4C is a graph showing electrical conductivity of 1.4×104-S/cm under areal strain up to 156%. The inset graphs in FIGS. 4B and 4C demonstrate cyclic stability over 10,000 cycles at each respective strain.

To verify whether the Au-PDMS 3D nanophase can be applied as a practical electrode, the relative resistance of the 3D Au-PDMS nanophase sample was measured using a two-terminal measurement method.

FIG. 4D shows a graph of uniaxial strain-dependent relative resistance changes in the 3D structure of Au-PDMS nanophase strap pads with various initial widths (w0=5, 4, 3, 2 and 1 mm). The “ideal” elastic conductor, indicated as “ideal” in the graph, is a hypothetical sample with strain-invariant resistance under two-terminal measurement, describing only the geometric changes in resistance with stretching, including considerations for the Poisson ratio.

The ideal elastic conductor showed a 2.5-fold increase in resistance under 100% uniaxial strain (ΔL/L0=1.0). Comparing this with the measured resistance changes of Au-PDMS, it can be observed that the resistance of the Au-PDMS nanophase with a width of 5 mm exhibits strain-invariant electrical conductivity, which significantly surpasses the performance of other state-of-the-art materials.

Even at 30% uniaxial strain (ΔL/L0-0.3), the resistance changes in the samples, except for those with a width of 1 mm, were lower than the resistance changes of the ideal elastic conductor.

FIG. 4E illustrates a graph of the areal strain-dependent relative resistance changes in the 3D structure of Au-PDMS nanophase disc-shaped pads. The “ideal” elastic conductor, marked as “ideal” in the graph, represents a hypothetical sample with strain-invariant resistivity.

The results for the example under areal strain and the resistance changes of the ideal elastic conductor showed a similar trend. However, the Au-PDMS 3D nanophase sample exhibited smaller resistance changes than the ideal elastic conductor, even under areal strain up to 156% (ΔL/L0=1.56).

FIG. 4F shows a confocal microscope scan image of the 3D structure in the Au-PDMS nanophase example. The line profiles extracted from dashed lines A and B demonstrate that the extensive specific surface area contributed to the strain-invariant conductivity.

### [Experimental Example 5] Environmental Resilience Testing-Analyzing Stability in Multimodal Conditions

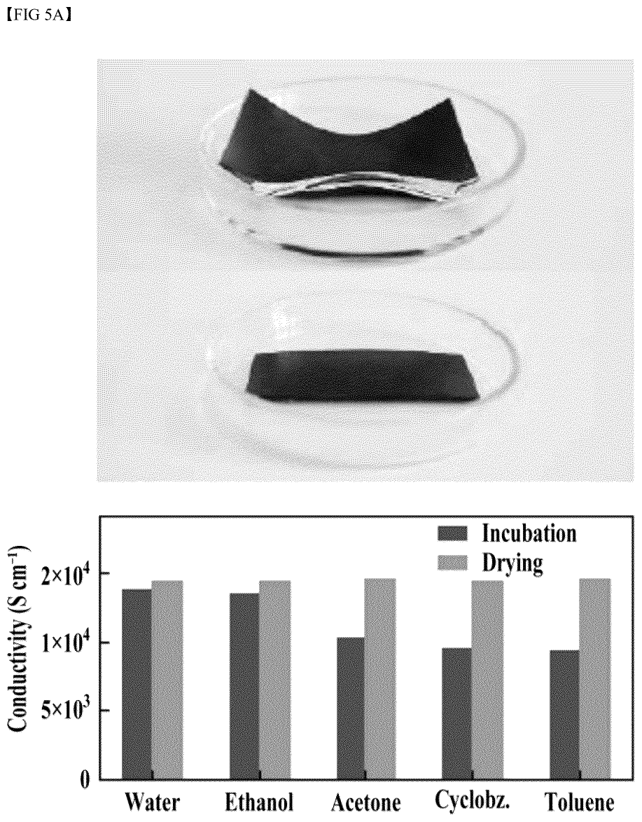

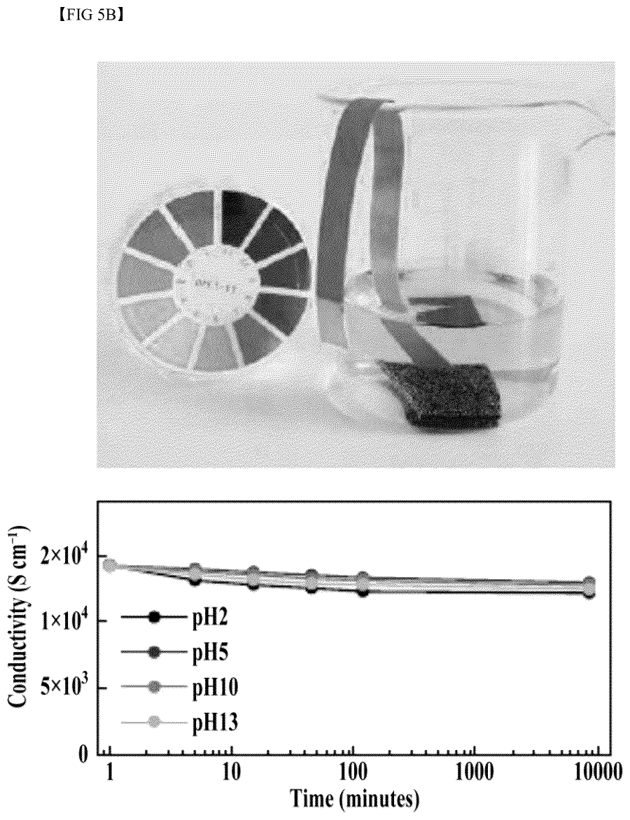

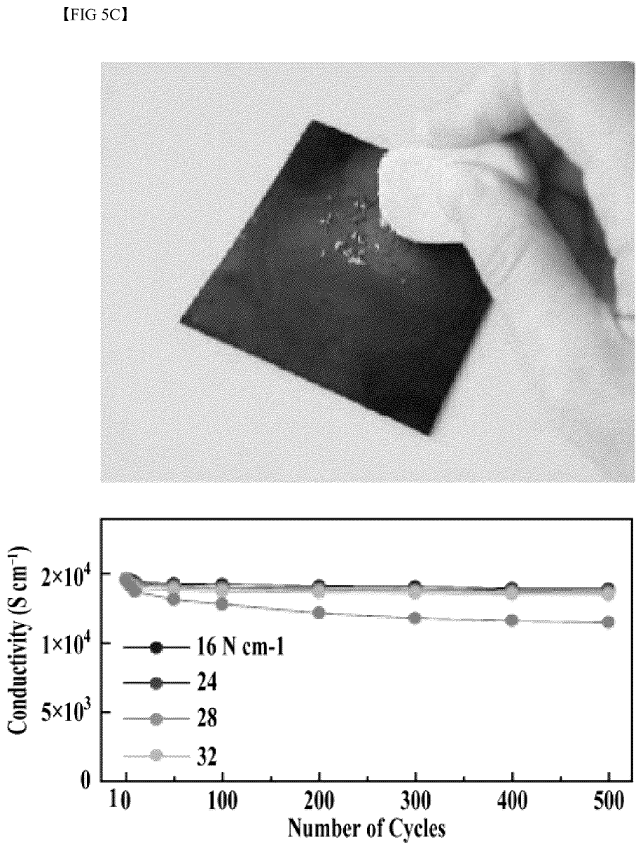

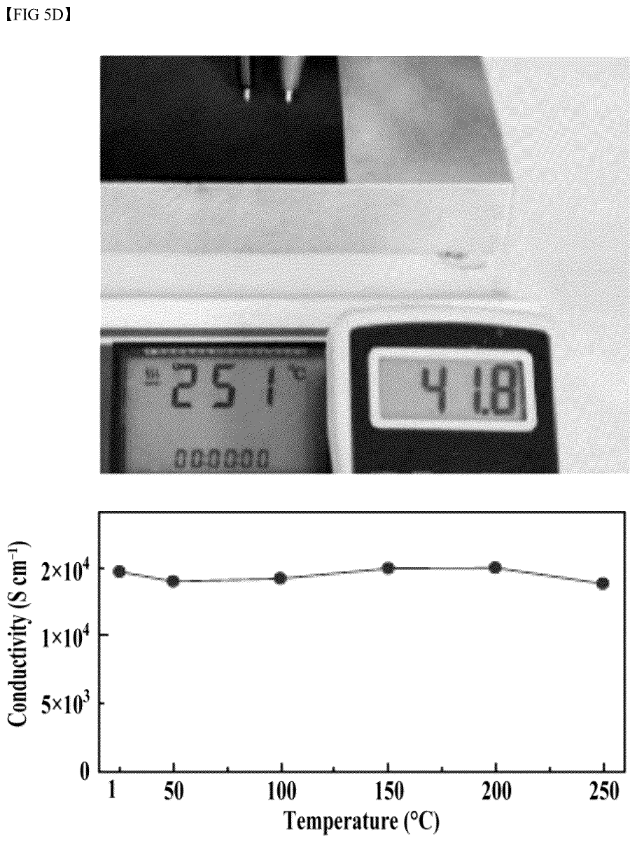

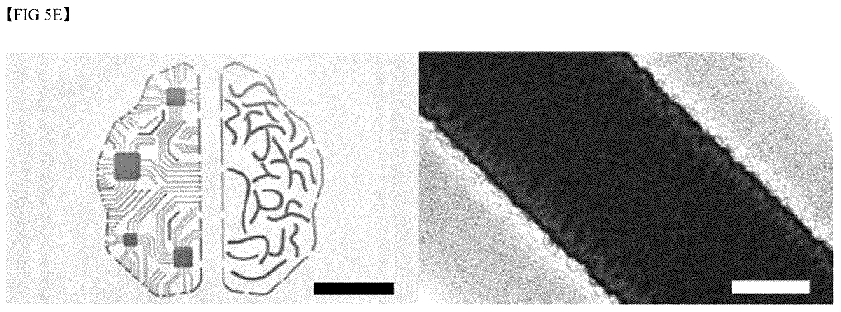

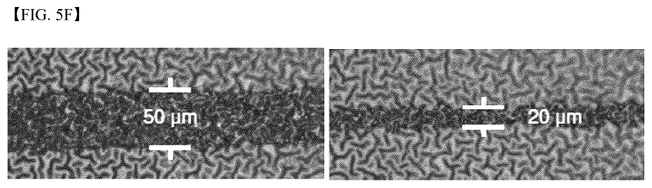

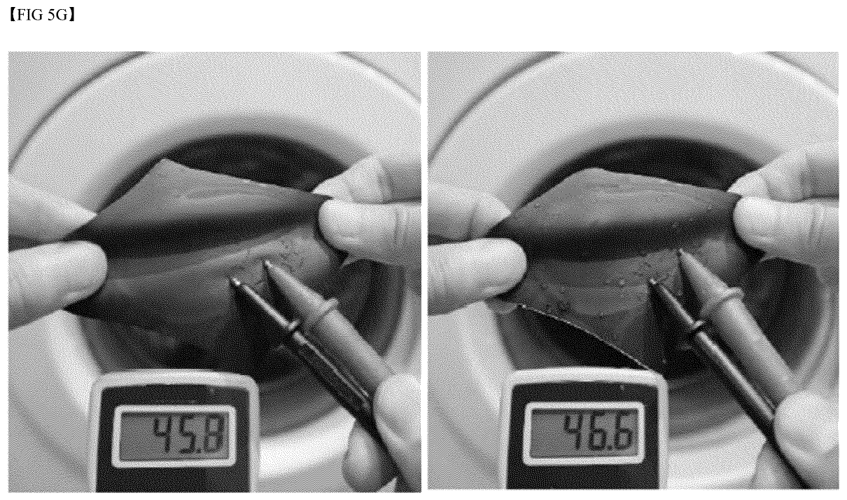

To evaluate chemical stability, environmental resilience tests were conducted under various conditions. First, Section 4 was soaked overnight in different solvents (water, ethanol, acetone, cyclobenzene, and toluene), and electrical conductivity was measured (indicated as “Incubation” in FIG. 5A). Subsequently, the sample was dehydrated overnight at 60° C., and electrical conductivity was measured again (indicated as “Drying” in FIG. 5A). The durability performance of the Au-PDMS nanoscale 3D structure in various organic solvents is shown in FIG. 5A. After one day of immersion in solvents of different polarities, the electrical conductivity of the nanoscale samples remained stable in polar solvents but slightly decreased in nonpolar solvents. This could be attributed to the expansion of the PDMS matrix in nonpolar solvents, causing deformation of the conductive network. However, after the nanoscale samples dried, the electrical conductivity almost completely recovered within a 5% margin of error.

Next, for pH stability testing, various pH conditions were created using HCl and KOH solutions. Section 4 was then immersed in these pH solutions for varying durations. The durability performance of the Au-PDMS nanoscale 3D structure measured at pH 2 to pH 13 is shown in FIG. 5B. Electrical conductivity was preserved even under such harsh pH conditions, demonstrating the material's suitability for bioelectronic applications related to the stomach (pH 1.3 to pH 3.5) and skin wounds (pH 7.2 to pH 8.9).

Next, for mechanical wear testing, tape adhesion tests and eraser tests were conducted. In the tape adhesion test, strong adhesive tape (3M) was repeatedly attached and removed from the 3D structured surface of Section 4 for 500 cycles. Changes in electrical conductivity were measured after each adhesion cycle. In the eraser test, the surface of the fabricated Au-PDMS nanoscale structure was repeatedly rubbed with an eraser (TOMBOW®) for a specified number of cycles. The frictional strength was determined by the non-contact area (2 cm×2 cm) and the applied pressing force (approximately 0.245 kPa), which is sufficient to generate eraser debris. The durability performance of the Au-PDMS nanoscale 3D structure measured in the eraser and tape adhesion tests is shown in FIG. 5C. In the graph of FIG. 5C, the red line represents the eraser test, while the other lines represent the tape adhesion test. The electrical conductivity of the Au-PDMS reticular nanoscale structure with cortical gyrification patterns remained almost entirely stable during 500 cycles of the tape adhesion test (in the range of 16˜32N cm⁻¹). Even after the wear test using the eraser, the electrical conductivity was maintained at the same level.

Next, thermal stability testing was conducted by heating Section 4 on a hot plate (SMHS-3, DAIHAN). After heating at various temperatures, the electrical conductivity of the sample was evaluated. The durability performance of the Au-PDMS nanoscale 3D structure, measured while heating up to 250° C., is shown in FIG. 5D. Unlike other thermoplastic elastomer-based stretchable electrodes, the Au-PDMS nanoscale structure with cortical gyrification patterns exhibited excellent thermal stability for up to 2 hours at 250° C. This expands its applicability for integration with functional elements requiring thermal annealing during manufacturing or operation at high temperatures, such as thermoelectric modules, heater modules, and heat sterilization processes.

FIG. 5E shows the results of patterning Section 4 using stencil mask lithography (black scale bar: 1 cm, white scale bar: 50 μm). Stencil mask lithography involves directly placing a metal stencil mask (0.1 mm thick stainless steel, Devora Electronics) onto a plain PDMS membrane (Φ=3.5, thickness 0.65 mm) without spacers. This method enables pattern formation without the need for photolithography.

For micro-patterning of integrated circuits, the photolithography of Au-PDMS nanoscale samples was performed following standard procedures. The samples were spin-coated with a positive photoresist (AZ 5214E®, MicroChemicals) and soft-baked at 110° C. for 2 minutes. Subsequently, the samples were exposed to a 365 nm UV light source (KLS-100H-LS-150P, DONGWOO Optron) using a patterned photomask. After exposure, the samples were immersed in a developer solution (AZ® 327, MicroChemicals) and vigorously agitated for 1 minute. To ensure complete curing of the remaining photoresist, a post-baking step was carried out at 190° C. for 10 minutes. Selective etching of the nanoscale structures was achieved by incubating them in aqua regia, a mixture of HCl and HNO₃ at a 9:1 volume ratio. For lift-off, a general-purpose photoresist stripper (AZ® 100, MicroChemicals) was used to remove the remaining photoresist.

High-resolution patterning of stretchable electrodes was achieved using conventional photolithography, and the results are shown in FIG. 5F. As previously discussed, the chemical and thermal durability of the Au-PDMS nanoscale samples enables micro-scale patterning with feature sizes of 20 μm and 50 μm through photolithography processes involving organic solvents and photoresist baking steps. This demonstrates the potential for application in complex circuit designs.

Next, for the washing test, Section 4 was washed at room temperature for 15 minutes using a washing machine (WW70T4042EE/EG, Samsung), with or without detergent (Persil Gel Detergent, Germany). This washing process was repeated 20 times to perform a cyclic washing test. The left image in FIG. 5G shows the nanoscale composite before washing, while the right image shows the nanoscale composite after washing with detergent, along with the analysis results of their electrical conductivity and stretchability. As shown, even after 20 cycles of machine washing for 15 minutes each with detergent, the nanoscale composite exhibited no degradation in electrical performance compared to its initial conductivity, and its stretchability remained nearly unchanged.

As described above, although the present invention has been explained with reference to limited embodiments and drawings, the invention is not limited to the aforementioned embodiments. Those skilled in the art to which the invention pertains will understand that various modifications and changes can be made based on the described disclosures.

Therefore, the scope of the present invention should not be construed as being limited to the described embodiments but should be defined by the appended claims and their equivalents.

What is claimed is:

1. A method of manufacturing a gyrified metal-elastomer composite, comprising:
mixing a prepolymer and a crosslinker to form an elastomer;
depositing a metal onto the elastomer to form a metal-elastomer composite with the metal embedded in the elastomer; and
self-forming gyrifications on the metal-elastomer composite.

2. The method of claim 1, wherein the step of forming the metal-elastomer composite comprises:
integrating the metal with the elastomer at the molecular level; and
facilitating the growth of the metal in the z-axis direction within the elastomer matrix.

3. The method of claim 2, wherein the step of facilitating the growth of the metal in the z-axis direction within the elastomer matrix comprises:
growing the metal in a form of nano-needles while being deposited.

4. The method of claim 1, wherein, when the prepolymer and the crosslinker are mixed in a weight ratio of 5:1 to 10:1, the deposited metal is deposited with a thickness of 7.5 nm to 12.5 nm.

5. The method of claim 1, wherein, when the prepolymer and the crosslinker are mixed in a weight ratio of 3.5:1 to 5:1, the deposited metal is deposited with a thickness of 12.5 nm to 37.5 nm.

6. The method of claim 1, wherein, when the prepolymer and the crosslinker are mixed in a weight ratio of 3:1 to 4:1, the deposited metal is deposited with a thickness of 37.5 nm to 87.5 nm.

7. The method of claim 1, wherein, when the prepolymer and the crosslinker are mixed in a weight ratio of 3:1 to 3.5:1, the deposited metal is deposited with a thickness of 87.5 nm to 125 nm.

8. The method of claim 1, wherein, when the prepolymer and the crosslinker are mixed in a weight ratio of 2.5:1 to 3.5:1, the deposited metal is deposited with a thickness of 125 nm to 250 nm.

9. The method of claim 1, wherein the step of self-forming gyrifications on the metal-elastomer composite comprises:
gyrifying the metal-elastomer composite.

10. The method of claim 1, wherein the step of self-forming gyrifications on the metal-elastomer composite is performed for 0.5 hours to 36 hours.

11. A gyrified metal-elastomer composite manufactured according to the method of claim 1.

12. The gyrified metal-elastomer composite of claim 11, wherein the gyrifications of the gyrified metal-elastomer composite have a gyrified structure.

13. The gyrified metal-elastomer composite of claim 11, wherein the gyrified metal-elastomer composite is characterized by the elastomer and the metal being chemically bonded at the nanoscale.

14. The gyrified metal-elastomer composite of claim 11, wherein the thickness of the metal in the gyrified metal-elastomer composite is from 10 nm to 10,000 nm.

15. The gyrified metal-elastomer composite of claim 11, wherein the electrical conductivity of the gyrified metal-elastomer composite is from 1.0×10² S/cm to 1.0×10⁶ S/cm under an areal strain of 100% to 156%.

16. The gyrified metal-elastomer composite of claim 11, wherein the gyrified metal-elastomer composite has an electrical conductivity of 1.0× 10²S/cm to 1.0×10⁶ S/cm in a solution with a pH of 2 to 13.
